(19) United States
(12) Patent Application Publication
(10) Pub. No.: US 2024/0098997 A1
(43) Pub. Date: Mar. 21, 2024

(54) SEMICONDUCTOR DEVICE AND METHOD FOR MANUFACTURING THE SAME

(71) Applicant: Kioxia Corporation, Tokyo (JP)

(72) Inventors: Ryosuke UMINO, Kuwana Mie (JP); Daisuke IKENO, Yokkaichi Mie (JP)

(73) Assignee: Kioxia Corporation, Tokyo (JP)

(21) Appl. No.: 18/450,187

(22) Filed: Aug. 15, 2023

(30) Foreign Application Priority Data
Sep. 15, 2022 (JP) 2022-147162

(51) Int. Cl. H10B 43/27

(52) U.S. Cl. CPC H10B 43/27

(57) ABSTRACT

A semiconductor device includes: a stacked film alternately including a plurality of electrode layers and a plurality of first insulating films; a charge storage layer provided on the side surfaces of the electrode layers via a second insulating film; and a semiconductor layer provided on the side surface of the charge storage layer via a third insulating film. At least one electrode layer of the plurality of electrode layers includes a first electrode layer which is an amorphous layer comprising a metal element and silicon.

### CROSS-REFERENCE TO RELATED APPLICATION(S)

This application is based upon and claims the benefit of priority from Japanese Patent Application No. 2022-147162, filed Sep. 15, 2022, the entire contents of which are incorporated herein by reference.

### FIELD

Embodiments described herein relate generally to a semiconductor device and a method for manufacturing the semiconductor device.

### BACKGROUND

For a three-dimensional semiconductor memory having electrode layers such as word lines, it is desired to reduce the electrical resistance of the electrode layers and to prevent an increase in leakage current caused by the electrode layers.

### DESCRIPTION OF THE DRAWINGS

FIG. 1 is a perspective view showing the structure of a semiconductor device according to a first embodiment.

FIG. 2 is a cross-sectional view (¼) illustrating a method for manufacturing the semiconductor device according to the first embodiment.

FIG. 3 is a cross-sectional view ( 2/4) illustrating the method for manufacturing the semiconductor device according to the first embodiment.

FIG. 4 is a cross-sectional view (¾) illustrating the method for manufacturing the semiconductor device according to the first embodiment.

FIG. 5 is a cross-sectional view ( 4/4) illustrating the method for manufacturing the semiconductor device according to the first embodiment.

FIGS. 6A and 6B are cross-sectional views showing the structure of a semiconductor device according to a first comparative example of the first embodiment.

FIGS. 7A and 7B are cross-sectional views showing the structure of a semiconductor device according to a second comparative example of the first embodiment.

FIGS. 8A and 8B are cross-sectional views showing the structure of a semiconductor device according to the first embodiment.

FIGS. 9A through 9D are diagrams illustrating the grain size D of crystal grains P3 in a metal layer 26 according to the first embodiment.

FIGS. 10A through 10C are cross-sectional views illustrating details of the method for manufacturing the semiconductor device according to the first embodiment.

FIGS. 11A through 11C are graphs showing properties of the semiconductor device according to the first embodiment.

FIGS. 12A through 12C are cross-sectional views showing details of the semiconductor device according to the first embodiment.

### DETAILED DESCRIPTION

At least one embodiment provides a semiconductor device having electrode layers with preferable properties, and a method for manufacturing the semiconductor device.

In general, according to at least one embodiment, a semiconductor device includes: a stacked film alternately including a plurality of electrode layers and a plurality of first insulating films; a charge storage layer provided on the side surfaces of the electrode layers via a second insulating film; and a semiconductor layer provided on the side surface of the charge storage layer via a third insulating film. At least one electrode layer of the plurality of electrode layers includes a first electrode layer which is an amorphous layer comprising a metal element and silicon.

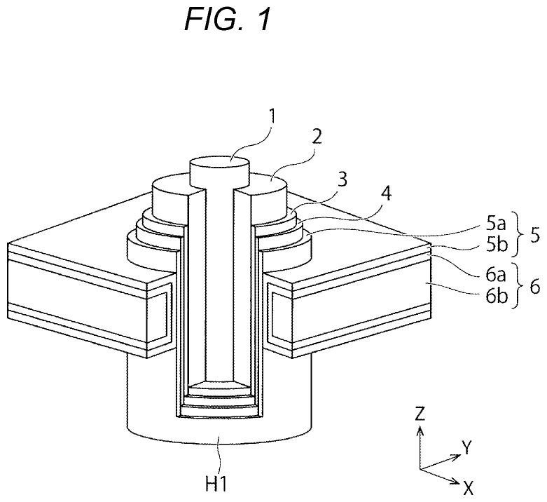

Embodiments of the present disclosure will now be described with reference to the drawings. In FIGS. 1 through 12, the same symbols are used for the same or similar components or elements, and a duplicated description thereof is omitted.

### First Embodiment

FIG. 1 is a perspective view showing the structure of a semiconductor device according to a first embodiment. The semiconductor device of this embodiment includes, for example, a three-dimensional semiconductor memory.

The semiconductor device of this embodiment includes a core insulating film 1, a channel semiconductor layer 2, a tunnel insulating film 3, a charge storage layer 4, a block insulating film 5, and electrode layers 6. The block insulating film 5 includes an insulating film 5a and an insulating film 5b. Each electrode layer 6 includes a barrier metal layer 6a and an electrode material layer 6b. The tunnel insulating film 3 is an example of a third insulating film. The insulating film 5a is an example of a second insulating film.

In FIG. 1, a plurality of electrode layers and a plurality of insulating films are stacked alternately on a substrate, and a memory hole H1 is provided in the electrode layers and the insulating films. FIG. 1 shows one electrode layer 6 of the electrode layers. The electrode layers function, for example, as word lines of a three-dimensional semiconductor memory. FIG. 1 shows an X direction and a Y direction, which are perpendicular to each other and parallel to the surface of the substrate, and a Z direction perpendicular to the surface of the substrate. As used herein, “+Z” direction refers to the upward Z direction, and “−Z” direction refers to the downward Z direction. The −Z direction may or may not coincide with the direction of gravity.

The core insulating film 1, the channel semiconductor layer 2, the tunnel insulating film 3, the charge storage layer 4, and the insulating film 5a are formed in the memory hole H1 and constitute memory cells of the three-dimensional semiconductor memory. The insulating film 5a is formed on the side surfaces of the electrode layers and the insulating films in the memory hole H1, and the charge storage layer 4 is formed on the side surface of the insulating film 5a. The charge storage layer 4 can store signal charges in the three-dimensional semiconductor memory. The tunnel insulating film 3 is formed on the side surface of the charge storage layer 4, and the channel semiconductor layer 2 is formed on the side surface of the tunnel insulating film 3. The channel semiconductor layer 2 functions as a channel of the three-dimensional semiconductor memory. The core insulating film 1 is formed on the side surface of the channel semiconductor layer 2.

The insulating film 5a is, for example, an SiO₂ film (silicon oxide film). The charge storage layer 4 is, for example, an SiN film (silicon nitride film). The tunnel insulating film 3 is, for example, an SiO₂ film. The channel semiconductor layer 2 is, for example, a polysilicon layer. The core insulating film 1 is, for example, an SiO₂ film.

The insulating film 5b, the barrier metal layer 6a, and the electrode material layer 6b are formed between two of the above-described insulating films; they are formed on the lower surface of the upper insulating film, on the upper surface of the lower insulating film, and on the side surface of the insulating film 5a. The insulating films are an example of first insulating films. The insulating film 5b is, for example, an Al₂O₃ film (aluminum oxide film). The barrier metal layer 6a is, for example, a TiN film (titanium nitride film). The electrode material layer 6b is, for example, a W (tungsten) layer. Further details of the electrode material layer 6b will be described later.

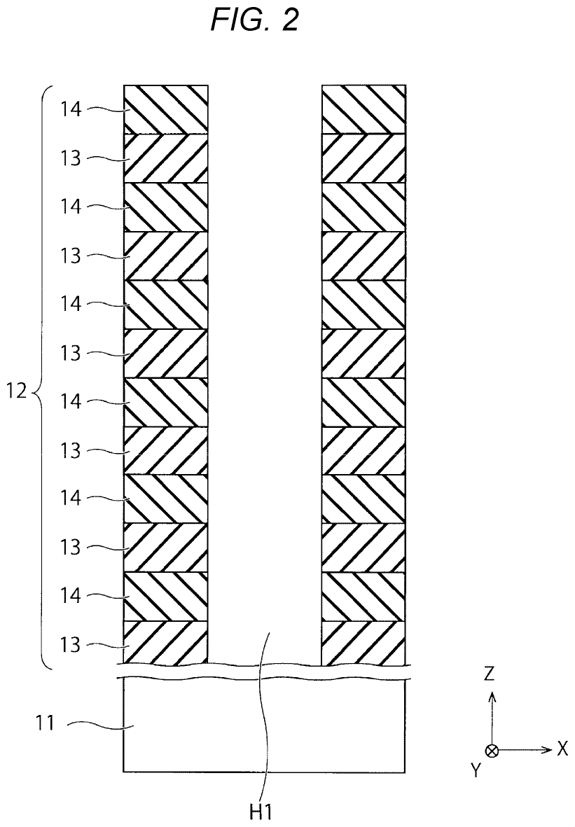

FIGS. 2 through 5 are cross-sectional views illustrating a method for manufacturing the semiconductor device according to the first embodiment.

First, a substrate 11 is prepared, and a stacked film 12 alternately including a plurality of sacrificial layers 13 and a plurality of insulating films 14 is formed on the substrate 11 (FIG. 2). The stacked film 12 is formed by alternately forming the sacrificial layers 13 and the insulating films 14 on the substrate 11. The stacked film 12 may be formed directly on the substrate 11, or may be formed on the substrate 11 via some layer. The substrate 11 is, for example, a semiconductor substrate such as an Si (silicon) substrate. Each sacrificial layer 13 is, for example, an SiN film. Each insulating film 14 is, for example, an SiO₂ film. The sacrificial layers 13 are an example of first layers, and the insulating films 14 are an example of first insulating films.

Next, a plurality of memory holes H1 are formed in the stacked film 12 by photolithography and RIE (Reactive Ion Etching) (FIG. 2). FIG. 2 shows one of the memory holes H1. Each memory hole H1 of this embodiment has a circular shape in a plan view, and penetrates the stacked film 12.

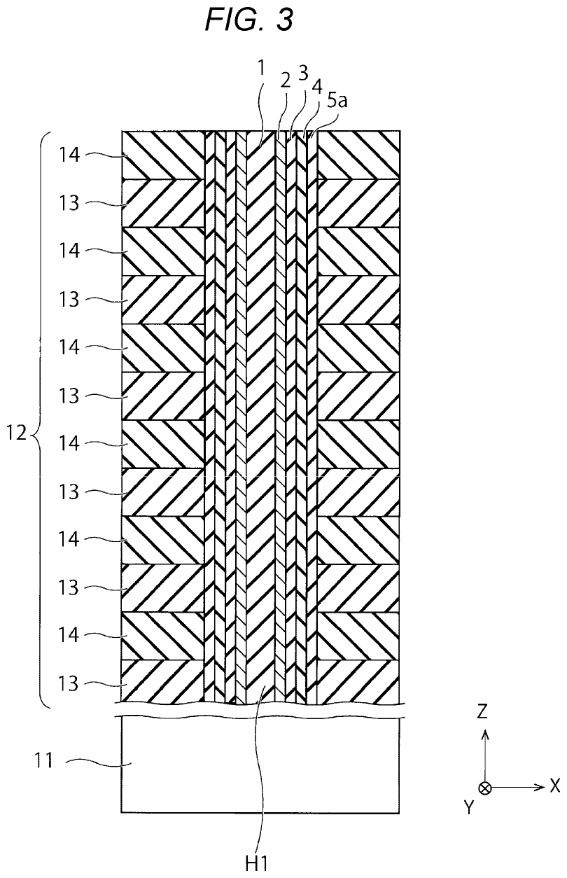

Next, an insulating film 5a, a charge storage layer 4, a tunnel insulating film 3, a channel semiconductor layer 2, and a core insulating film 1 are formed in this order on the side surface of the stacked film 12 in each memory hole H1 (FIG. 3). The insulating film 5a, the charge storage layer 4, the tunnel insulating film 3, and the channel semiconductor layer 2 are formed in a tubular shape extending in the Z direction. The core insulating film 1 is formed in a columnar shape extending in the Z direction.

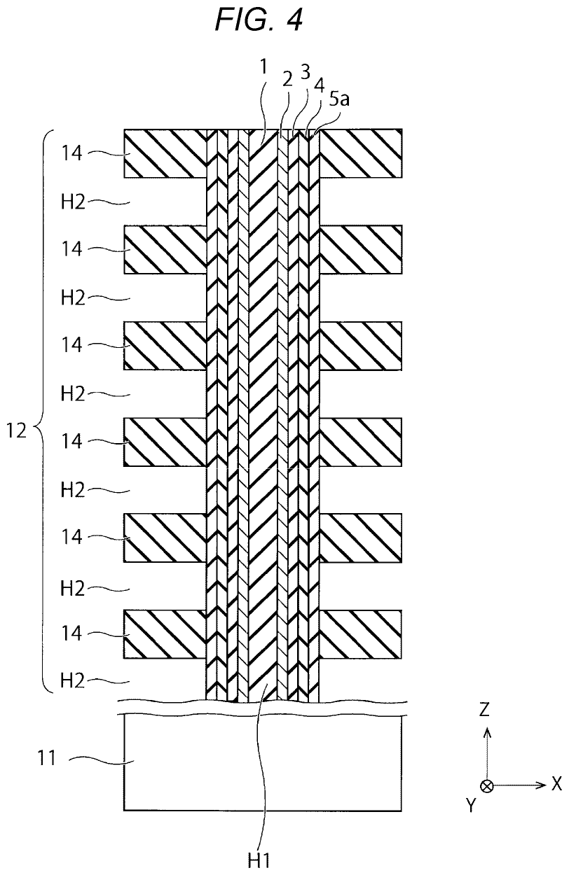

Next, a plurality of slits (not shown) are formed in the stacked film 12, and a liquid chemical such as an aqueous phosphoric acid solution is supplied through the slits to remove the sacrificial layers 13. As a result, a plurality of recesses H2 are formed in the stacked film 12 (FIG. 4). The recesses H2 are an example of first recesses.

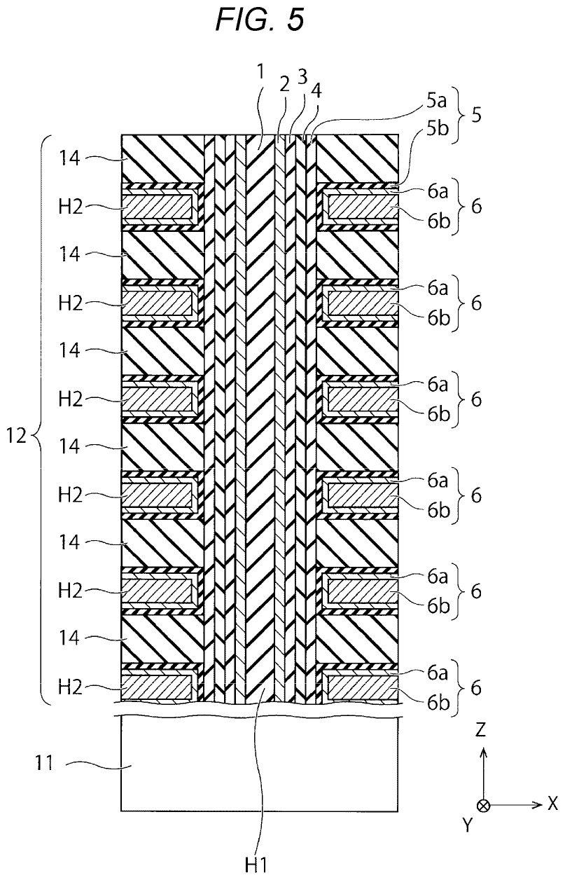

Next, an insulating film 5b, a barrier metal layer 6a, and an electrode material layer 6b are formed in this order on the surfaces of the insulating film 5a and the insulating films 14 in each recess H2 (FIG. 5). As a result, a block insulating film 5 including the insulating films 5a, 5b is formed. An electrode layer 6, including the barrier metal layer 6a and the electrode material layer 6b, is formed in each recess H2. Further, a stacked film 12, alternately including the electrode layers 6 and the insulating films 14, is formed on the substrate 11. A replacement step, which involves replacing the sacrificial layers 13 with the electrode layers 6, is performed in this manner.

Each recess H2 is formed between two insulating films 14 adjacent to each other in the Z direction. In each recess H2, the insulating film 5b, the barrier metal layer 6a, and the electrode material layer 6b are formed in this order on the lower surface of the upper insulating film 14, the upper surface of the lower insulating film 14, and the side surface of the insulating film 5a. As a result, each electrode layer 6 is formed between the insulating films 14 via the insulating film 5b.

The semiconductor device of this embodiment is manufactured in this manner (FIG. 5). FIG. 1 shows part of the semiconductor device shown in FIG. 5.

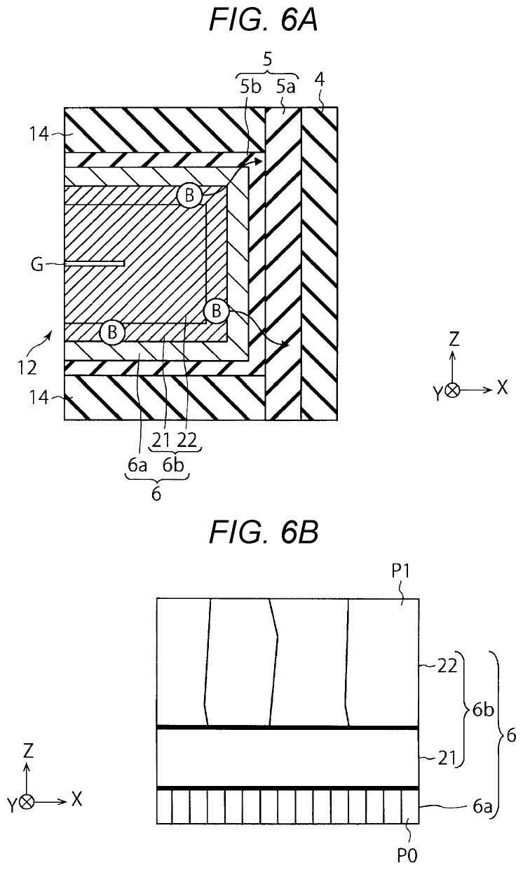

A comparison will now be made between the first embodiment and comparative examples with reference to FIGS. 6 through 8.

FIGS. 6A and 6B are cross-sectional views showing the structure of a semiconductor device according to a first comparative example of the first embodiment.

As with FIG. 5, FIG. 6A shows the charge storage layer 4, the block insulating film 5, the electrode layer 6, the insulating films 14, etc. FIG. 6A further shows the barrier metal layer 6a and the electrode material layer 6b in the electrode layer 6, and an air gap G in the electrode material layer 6b. As shown in FIG. 6A, the electrode material layer 6b of this comparative example includes metal layers 21, 22 formed in this order on the side surface, the upper surface, and the lower surface of the barrier metal layer 6a.

The metal layer 21 is a W layer formed using WF₆ gas and B₂H₆ gas (W represents tungsten, F represents fluorine, B represents boron, and H represents hydrogen). Therefore, the metal layer 21 contains B atoms as impurity atoms. If B atoms in the metal layer 21 diffuse into the block insulating film 5, then there is a fear of deterioration of the erasing characteristics of a memory cell, and a fear of an increase in leakage current in a memory cell. Meanwhile, the metal layer 22 is a W layer formed using WF₆ gas and H₂ gas.

FIG. 6B shows an enlarged view of the electrode layer 6 shown in FIG. 6A. The thick lines in FIG. 6B represent the interface between the barrier metal layer 6a and the metal layer 21, and the interface between the metal layer 21 and the metal layer 22. The thin lines in FIG. 6B represent grain boundaries between crystal grains P0 in the barrier metal layer 6a, and grain boundaries between crystal grains P1 in the metal layer 22.

In this comparative example, the barrier metal layer 6a and the metal layer 22 are polycrystalline layers, while the metal layer 21 is an amorphous layer. The metal layer 21 is formed as an amorphous layer by forming the metal layer 21 using WF₆ gas and B₂H₆ gas. When the metal layer 22 is formed on the surface of the barrier metal layer 6a via the metal layer 21, the crystallinity of the barrier metal layer 6a does not significantly affect the crystallinity of the metal layer 22 due to the action of the metal layer 21. It is therefore possible to make the grain size of the crystal grains P1 in the metal layer 22 large even when the grain size of the crystal grains P0 in the barrier metal layer 6a is small. This makes it possible to reduce the electrical resistance of the metal layer 22 (electrode layer 6). However, in this comparative example, diffusion of B atoms from the metal layer 21 may cause problems as described above.

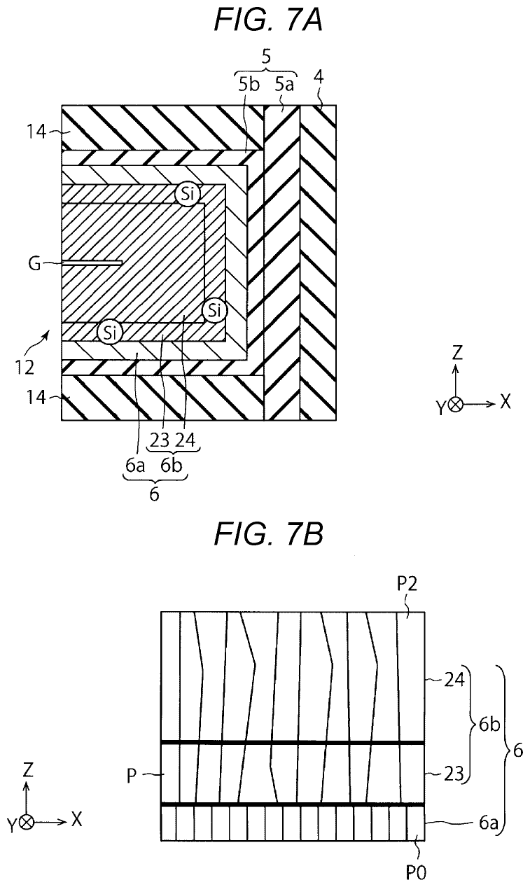

FIGS. 7A and 7B are cross-sectional views showing the structure of a semiconductor device according to a second comparative example of the first embodiment.

FIG. 7A shows a cross-sectional view similar to FIG. 6A. As shown in FIG. 7A, the electrode material layer 6b of this comparative example includes metal layers 23, 24 formed in this order on the side surface, the upper surface, and the lower surface of the barrier metal layer 6a.

The metal layer 23 is a W layer formed using WF₆ gas and SiH₄ gas (Si represents silicon). Thus, the metal layer 23 contains Si atoms, not B atoms, as impurity atoms. This makes it possible to avoid the problems associated with the diffusion of B atoms. The metal layer 23 is formed, for example, at a temperature higher than 300° C. Meanwhile, the metal layer 24 is a W layer formed using WF₆ gas and H₂ gas.

FIG. 7B shows an enlarged view of the electrode layer 6 shown in FIG. 7A. The thick lines in FIG. 7B represent the interface between the barrier metal layer 6a and the metal layer 23, and the interface between the metal layer 23 and the metal layer 24. The thin lines in FIG. 7B represent grain boundaries between crystal grains PO in the barrier metal layer 6a, grain boundaries between crystal grains P in the metal layer 23, and grain boundaries between crystal grains P2 in the metal layer 24.

In this comparative example, the barrier metal layer 6a, the metal layer 23 and the metal layer 24 are all polycrystalline layers. The metal layer 23 is formed as a polycrystalline layer by forming the metal layer 23 at a temperature higher than 300° C. using WF₆ gas and SiH₄ gas. When the metal layer 24 is formed on the surface of the barrier metal layer 6a via the metal layer 23, the crystallinity of the barrier metal layer 6a affects the crystallinity of the metal layer 23, and the crystallinity of the metal layer 23 affects the crystallinity of the metal layer 24. Thus, when the grain size of the crystal grains PO in the barrier metal layer 6a is small, the grain size of the crystal grains P2 in the metal layer 24 is also small. Therefore, the metal layer 24 (electrode layer 6) has a high electrical resistance. Thus, while the semiconductor device of this comparative example can avoid the problems associated with the diffusion of B atoms, it has the problem of small grain size of the crystal grains P2 in the metal layer 24.

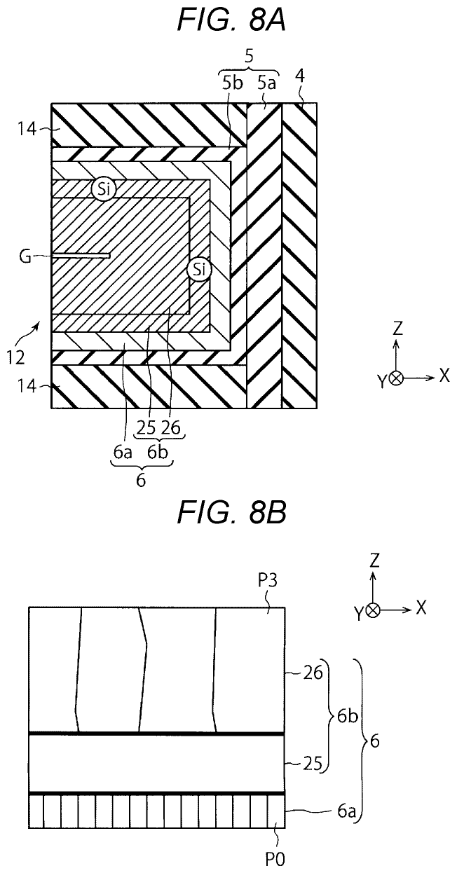

FIGS. 8A and 8B are cross-sectional views showing the structure of the semiconductor device according to the first embodiment.

FIG. 8A shows a cross-sectional view similar to FIG. 6A and FIG. 7A. As shown in FIG. 8A, the electrode material layer 6b of this embodiment includes metal layers 25, 26 formed in this order on the side surface, the upper surface, and the lower surface of the barrier metal layer 6a. The metal layer 25 is an example of a first electrode layer, and the metal layer 26 is an example of a second electrode layer.

The metal layer 25, like the metal layers 21, 23, comprises a metal element and silicon (Si). The metal element is, for example, tungsten (W). The metal layer 25 of this embodiment is a W layer formed using a material gas comprising W and a halogen element, and a reducing gas comprising Si and H. An example of the material gas is WF₆ gas. Examples of the reducing gas include SiH₄ gas and Si₂H₆ gas. Thus, the metal layer 25 of this embodiment contains Si atoms, not B atoms, as impurity atoms. This makes it possible to avoid the problems associated with the diffusion of B atoms. The metal layer 25 is formed, for example, at a temperature of not more than 300° C., preferably at a temperature of not more than 200° C.

The metal layer 25 may contain B atoms at such a low concentration that the problems associated with the diffusion of B atoms are not serious. For example, the metal layer 25 may contain B atoms which have been diffused from another layer. In at least one embodiment, if the metal layer 25 contains a low concentration of B atoms, the B concentration of the metal layer 25 is lower than the Si concentration of the metal layer 25. The Si concentration of the metal layer 25 is, for example, 6.0×10²¹ to 1.5×10²² atoms/cm³. The Si concentration of the metal layer 25 varies, for example, depending on the temperature at which the metal layer 25 is formed. When the number of W atoms in the metal layer 25 is represented by N1 and the number of Si atoms in the metal layer 25 is represented by N2, the compositional ratio N2/(N1+N2) of the Si atoms in the metal layer 25 is, for example, 0.10 to 0.15 (10-15%). That is, the metal layer 25 contains mainly tungsten. The metal layer 25 contains more tungsten atoms than silicon atoms.

The metal layer 26, like the metal layers 22, 24, comprises a metal element. The metal layer 26 of this embodiment comprises the same metal element as the metal layer 25. The metal element is, for example, tungsten (W). The metal layer 26 is, for example, a W layer formed using WF₆ gas as a material gas and H₂ gas as a reducing gas. The metal layer 26 is formed, for example, at a temperature higher than the temperature at which the metal layer 25 is formed. The temperature for forming the metal layer 25 is an example of a first temperature, and the temperature for forming the metal layer 26 is an example of a second temperature.

FIG. 8B shows an enlarged view of the electrode layer 6 shown in FIG. 8A. The thick lines in FIG. 8B represent the interface between the barrier metal layer 6a and the metal layer 25, and the interface between the metal layer 25 and the metal layer 26. The thin lines in FIG. 8B represent grain boundaries between crystal grains PO in the barrier metal layer 6a, and grain boundaries between crystal grains P3 in the metal layer 26.

In this embodiment, the barrier metal layer 6a and the metal layer 26 are polycrystalline layers, while the metal layer 25 is an amorphous layer. The metal layer 25 is formed as an amorphous layer by forming the metal layer 25 at a temperature of not more than 300° C. using the above-described material gas and reducing gas. When the metal layer 26 is formed on the surface of the barrier metal layer 6a via the metal layer 25, the crystallinity of the barrier metal layer 6a does not significantly affect the crystallinity of the metal layer 26 due to the action of the metal layer 25. It is therefore possible to make the grain size of the crystal grains P3 in the metal layer 26 large even when the grain size of the crystal grains PO in the barrier metal layer 6a is small. This makes it possible to reduce the electrical resistance of the metal layer 26 (electrode layer 6). According to this embodiment, it becomes possible to make the grain size of the crystal grains P3 in the metal layer 26 large while avoiding the problems associated with the diffusion of B atoms.

The average grain size of the crystal grains P3 in the metal layer 26 is, for example, not less than 50 nm. The thickness (Z-direction length) of the metal layer 26 of this embodiment is, for example, 25 nm or less. Therefore, according to this embodiment, it becomes possible to make the average grain size of the crystal grains P3 in the metal layer 26 at least twice the thickness of the metal layer 26. Further details of the average grain size of the crystal grains P3 in the metal layer 26 will be described below.

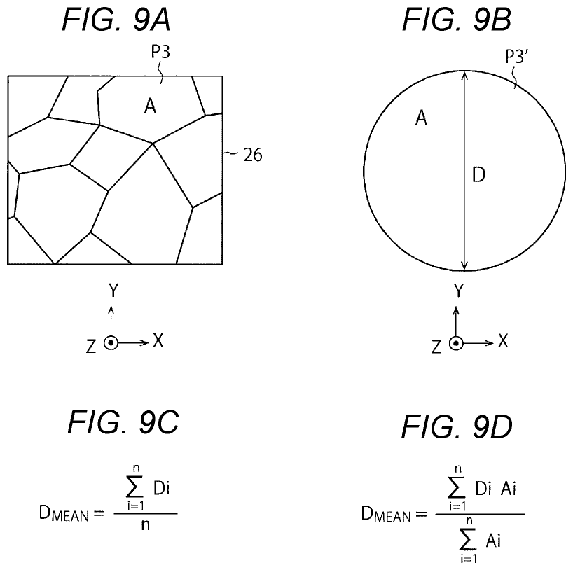

FIGS. 9A through 9D are diagrams illustrating the grain size D of the crystal grains P3 in the metal layer 26 of the first embodiment.

FIG. 9A shows an example of an XY cross-section of the metal layer 26. The XY cross-section shown in FIG. 9A includes cross-sections of a plurality of crystal grains P3 in the metal layer 26. FIG. 9A also shows the cross-sectional area A of a crystal grain P3 in the metal layer 26.

FIG. 9B shows a circle P3′ corresponding to the crystal grain P3. Assume that the area of the circle P3′ is the same as the area A of the crystal grain P3. FIG. 9B further shows the diameter D of the circle P3′. The relation A=π(D/2)² holds for the area A and the diameter D. Assume that in this embodiment, the grain size of the crystal grain P3 is represented by the diameter D of the circle P3′. Thus, the grain size of the crystal grain P3 having the area A is assumed to be D (=(4A/α)^{1/2}).

FIG. 9C shows a frequency average grain size as an example of the average grain size DMEAN of a plurality of crystal grains P3 in the metal layer 26. When n crystal grains P3 are present in an XY cross-section of the metal layer 26, the average grain size DMEAN of the crystal grains P3, in terms of the frequency average grain size, is expressed by the equation D_{MEAN}=(ΣDi)/n, where Di represents the grain size D of an i-th crystal grain P3, ΣDi represents the sum of the grain sizes D of the first to n-th crystal grains P3, n represents an integer equal to or greater than 2,and i represents an integer that satisfies 1≤i≤n.

FIG. 9D shows a weighted average grain size as an example of the average grain size DMEAN of a plurality of crystal grains P3 in the metal layer 26. When n crystal grains P3 are present in an XY cross-section of the metal layer 26, the average grain size DMEAN of the crystal grains P3, in terms of the weighted average grain size, is expressed by the equation DMEAN =(ZDiAi)/(ZAi), where Ai represents the area A of an i-th crystal grain P3, ZAi represents the sum of the areas A of the first to n-th crystal grains P3, and ZDiAi represents the sum of the DA values of the first to n-th crystal grains P3.

In this embodiment, the average grain size DMEAN of the crystal grains P3 in the metal layer 26 is expressed in terms of the weighted average grain size. As described above, the average (weighted average) grain size DMEAN of the crystal grains P3 in the metal layer 26 is, for example, not less than 50 nm. The thickness of the metal layer 26 of this embodiment is, for example, 25 nm or less. Therefore, according to this embodiment, it becomes possible to make the average (weighted average) grain size DMEAN of the crystal grains P3 in the metal layer 26 at least twice the thickness of the metal layer 26.

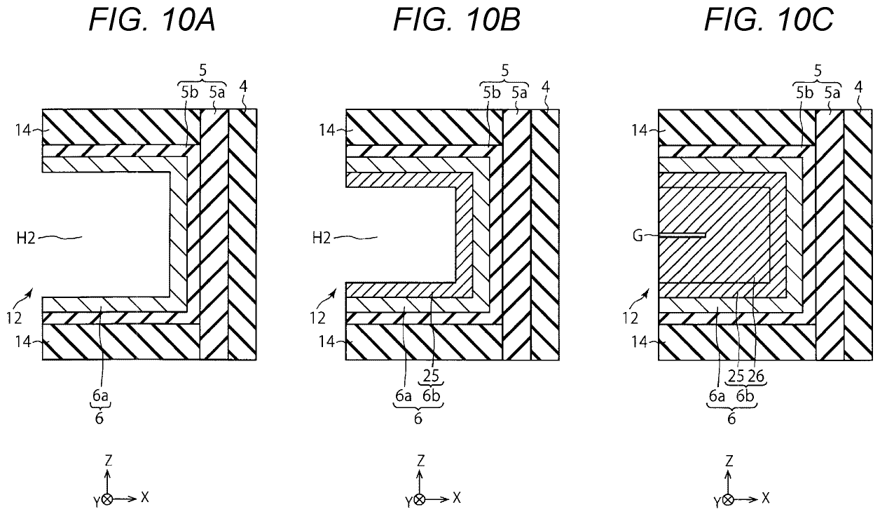

FIGS. 10A through 10C are cross-sectional views illustrating details of the method for manufacturing the semiconductor device according to the first embodiment.

When forming an electrode layer 6 in each recess H2, a barrier metal layer 6a is first formed on the surface of an insulating film 5b (FIG. 10A). The barrier metal layer 6a is, for example, a TiN film and is formed using TiCl₄ gas and NH₃ gas (Cl represents chlorine).

Next, a metal layer 25 is formed on the surface of the barrier metal layer 6a (FIG. 10B). The metal layer 25 is, for example, a W layer and is formed using WF₆ gas and SiH₄ (or Si₂H₆) gas. The metal layer 25 of this embodiment is formed as an amorphous layer, for example at a temperature of not more than 300° C. (preferably not more than 200° C.). The metal layer 25 of this embodiment is formed as an initial film of an electrode material layer 6b.

Next, a metal layer 26 is formed on the surface of the metal layer 25 (FIG. 10C). The metal layer 26 is, for example, a W layer and is formed using WF₆ gas and H₂ gas. The metal layer 26 is formed as a polycrystalline layer in the process step of FIG. 10C. The metal layer 26 of this embodiment is formed at a temperature which is higher than the temperature at which the metal layer 25 is formed, and is formed as a polycrystalline layer e.g. at 450° C. The metal layer 25 may change from an amorphous layer to a polycrystalline layer during or after the formation of the metal layer 26. In that case, the metal layer 25 is crystallized by annealing, for example at a temperature of not less than 600° C., preferably at a temperature of not less than 750° C., so that it changes from an amorphous layer to a polycrystalline layer. The metal layer 26 of this embodiment, together with the metal layer 25, forms an electrode material layer 6b. The metal layer 26 of this embodiment may be formed such that it has an air gap G.

The transition from the process step of FIG. 10A to the process step of FIG. 10B is performed, for example, ex situ. The transition from the process step of FIG. 10B to the process step of FIG. 10C is performed, for example, in situ.

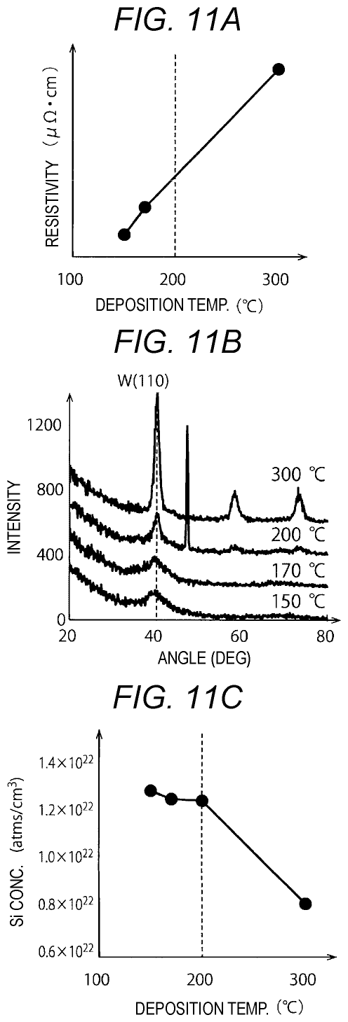

FIGS. 11A through 11C are graphs showing properties of the semiconductor device according to the first embodiment.

FIG. 11A shows the resistivity of the electrode material layer 6b (metal layers 25, 26). The abscissa axis of FIG. 11A represents the temperature (deposition temperature) at which the metal layer 25 is formed by CVD (Chemical Vapor Deposition). The ordinate axis of FIG. 11A represents the resistivity of the electrode material layer 6b in the semiconductor device after manufacture. As can be seen in FIG. 11A, the resistivity of the electrode material layer 6b increases significantly with increase in the deposition temperature when the deposition temperature is in the range of 200° C. to 300° C. Therefore, the deposition temperature in this embodiment is set to, for example, 300° C. or lower, preferably 200° C. or lower.

FIG. 11B shows the intensities of scattered X-rays as measured when the metal layer 25 is irradiated with X-rays immediately after the process step of FIG. 10B. In particular, FIG. 11B shows the intensities of scattered X-rays as measured at deposition temperatures of 150° C., 170° C., 200° C. and 300° C. in varying directions at an angle of 20 degrees to 80 degrees with the metal layer 25. As shown in FIG. 11B, a high peak appears in the intensity of scattered X-rays at a deposition temperature of 300° C. This indicates that the metal layer 25 changes from an amorphous layer to a polycrystalline layer at a deposition temperature of around 300° C.

FIG. 11C shows the Si concentration of the metal layer 25. The abscissa axis of FIG. 11C represents the temperature (deposition temperature) at which the metal layer 25 is formed by CVD. The ordinate axis of FIG. 11C represents the Si concentration of the metal layer 25 in the semiconductor device after manufacture. As can be seen in FIG. 11C, the Si concentration of the metal layer 25 increases with decrease in the deposition temperature, and reaches saturation at a deposition temperature of around 200° C.

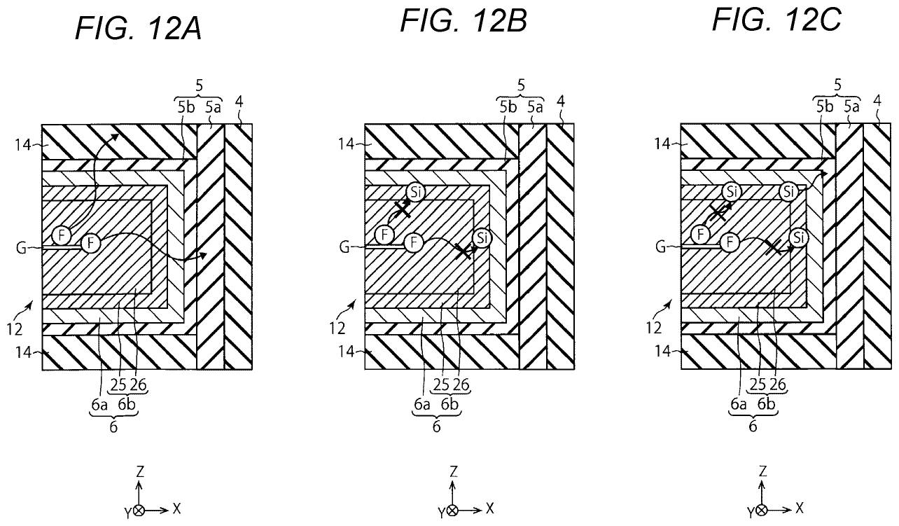

FIGS. 12A through 12C are cross-sectional views showing details of the semiconductor device according to the first embodiment.

FIG. 12A shows the metal layer 25, etc. when the Si concentration of the metal layer 25 is lower than 6.0×10²¹ atoms/cm³. In this case, if F atoms derived from WF₆ gas are generated upon the formation of the metal layer 26, the F atoms can diffuse into the block insulating film 5. The diffused F atoms may cause damage to the block insulating film 5.

FIG. 12B shows the metal layer 25, etc. when the Si concentration of the metal layer 25 is 6.0×10²¹ to 1.5×10²² atoms/cm³. In this case, the above-described F atoms are likely to react with Si atoms in the metal layer 25 to form Si—F bonds. This makes it possible to prevent diffusion of F atoms into the block insulating film 5.

FIG. 12C shows the metal layer 25, etc. when the Si concentration of the metal layer 25 is higher than 1.5×10²² atoms/cm³. Also in this case, F atoms can be prevented from diffusing into the block insulating film 5. However, since the metal layer 25 contains a large amount of Si atoms, Si atoms in the metal layer 25 are likely to diffuse into the block insulating film 5. Such diffused Si atoms can cause damage to the block insulating film 5.

Therefore, it is preferred that the Si concentration of the metal layer 25 is neither too high nor too low. Thus, the Si concentration of the metal layer 25 of this embodiment is preferably 6.0×10²¹ to 1.5×10²² atoms/cm³.

As described hereinabove, the electrode material layer 6b of this embodiment is formed of the metal layer 25 and the metal layer 26. Therefore, according to this embodiment, it becomes possible to form the electrode material layer 6b (electrode layer 6) having preferable properties. For example, the electrical resistance of the electrode layer 6 can be reduced by increasing the grain size of the crystal grains in the metal layer 26. Further, by forming the metal layer 25 without using a gas containing boron, it becomes possible to prevent an increase in leakage current caused by the electrode layer 6. Further, by setting the Si concentration of the metal layer 25 to 6.0×10²¹ to 1.5×10²² atoms/cm³, F atoms and Si atoms in the electrode layer 6 can be prevented from causing damage to the block insulating film 5.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A semiconductor device comprising:
a stacked film alternately including a plurality of electrode layers and a plurality of first insulating films;
a charge storage layer disposed on the side surfaces of the plurality of electrode layers via a second insulating film; and
a semiconductor layer disposed on the side surface of the charge storage layer via a third insulating film,
wherein at least one electrode layer of the plurality of electrode layers includes a first electrode layer, the first electrode layer being an amorphous layer comprising a metal element and silicon.

2. The semiconductor device according to claim 1, wherein the metal element is tungsten.

3. The semiconductor device according to claim 1, wherein the silicon concentration of the first electrode layer is 6.0×10²¹ to 1.5×10²² atoms/cm³.

4. The semiconductor device according to claim 1, wherein the silicon concentration of the first electrode layer is higher than the boron concentration of the first electrode layer.

5. The semiconductor device according to claim 1, wherein the at least one electrode layer further includes a second electrode layer which is a polycrystalline layer comprising the metal element.

6. A semiconductor device comprising:
a stacked film alternately including a plurality of electrode layers and a plurality of first insulating films;
a charge storage layer disposed on the side surfaces of the plurality of electrode layers via a second insulating film; and
a semiconductor layer disposed on the side surface of the charge storage layer via a third insulating film,
wherein at least one electrode layer of the plurality of electrode layers includes a first electrode layer and a second electrode layer, the first electrode layer comprising a metal element and silicon, the second electrode layer comprising crystal grains having an average grain size of not less than 50 nm.

7. The semiconductor device according to claim 6, wherein the first electrode layer is an amorphous layer comprising the metal element and silicon.

8. The semiconductor device according to claim 6, wherein the first electrode layer is a polycrystalline layer comprising the metal element and silicon.

9. The semiconductor device according to claim 6, wherein the second electrode layer is a polycrystalline layer comprising the metal element and comprising the crystal grains, the crystal grains having an average grain size of not less than 50 nm.

10. The semiconductor device according to claim 6, wherein the average grain size of the crystal grains in the second metal layer is at least twice the thickness of the second metal layer.

11. The semiconductor device according to claim 6, wherein the metal element is tungsten.

12. The semiconductor device according to claim 6, wherein the silicon concentration of the first electrode layer is 6.0×10²¹ to 1.5×10²² atoms/cm³.

13. The semiconductor device according to claim 6, wherein the silicon concentration of the first electrode layer is higher than the boron concentration of the first electrode layer.

14. The semiconductor device according to claim 6, wherein the first electrode layer is disposed (i) on the side surface of the second insulating film, (ii) on the upper surface of one of the first insulating films, and (iii) on the lower surface of another one of the first insulating films, and
wherein the second electrode layer is disposed (i) on the side surface of the second insulating film, (ii) on the upper surface of the one of the first insulating films, and (iii) on the lower surface of the another one of the first insulating films via the first electrode layer.

15. A method for manufacturing a semiconductor device, comprising:
forming a stacked film alternately including a plurality of first layers and a plurality of first insulating films;
forming a charge storage layer on the side surfaces of the plurality of first layers via a second insulating film;
forming a semiconductor layer on the side surface of the charge storage layer via a third insulating film;
removing the plurality of first layers to form first recesses in the stacked film; and
forming a plurality of electrode layers in the first recesses,
wherein at least one electrode layer of the plurality of electrode layers includes a first electrode layer comprising a metal element and silicon, and
wherein the first electrode layer is formed at a temperature of not more than 300° C. using a gas containing the metal element, and a reducing gas containing silicon.

16. The method for manufacturing a semiconductor device according to claim 15, wherein the reducing gas comprises silicon and hydrogen.

17. The method for manufacturing a semiconductor device according to claim 15, wherein the silicon concentration of the first electrode layer is 6.0×10²¹ to 1.5×10²² atoms/cm³.

18. The method for manufacturing a semiconductor device according to claim 15, wherein the at least one electrode layer further includes a second electrode layer comprising crystal grains having an average grain size of not less than 50 nm.

19. The method for manufacturing a semiconductor device according to claim 18, wherein the first electrode layer is formed at a first temperature, and the second electrode layer is formed at a second temperature higher than the first temperature.

20. The method for manufacturing a semiconductor device according to claim 18, wherein the second electrode layer is formed after the formation of the first electrode layer.
